(19) United States
(12) Patent Application Publication
(10) Pub. No.: US 2013/0187051 A1
(43) Pub. Date: Jul. 25, 2013

(54) FREQUENCY MULTIPLEXED SUPERCONDUCTING NANOWIRE PHOTON DETECTORS

(71) Applicant: Massachusetts Institute of Technology, Cambridge, MA (US)

(72) Inventors: Adam N. McCaughan, Cambridge, MA (US); Karl K. Berggren, Arlington, MA (US)

(73) Assignee: Massachusetts Institute of Technology, Cambridge, MA (US)

(21) Appl. No.: 13/633,472

(22) Filed: Oct. 2, 2012

Related U.S. Application Data
(60) Provisional application No. 61/543,885, filed on Oct. 6, 2011.

(51) Int. Cl. H01L 39/02

(52) U.S. Cl. CPC H01L 39/02; B82Y 15/00
USPC 250/340; 250/208.2; 250/394; 977/954

(57) ABSTRACT

A photon detection system with improved high-speed performance. An array of photon detectors is provided, providing transient responses that indicate both a time and a location of photon detection. Each photon detector may use a superconducting nanowire, arranged as part of a resonant cell to have a unique resonant frequency. Upon detection of even a single photon, a resonant cell may create a transient response comprising its unique resonant frequency. The transient responses may be combined on a single readout line, allowing identification of the photon detection location based on a detected frequency component read out. The electrical properties within resonant cells, as well as the connections between different resonant cells, may be configured to produce different transient responses. For example, resonant cells may be configured to produce a transient response having multiple pulses, which may separately indicate a time and a location of a photon detection.

### RELATED APPLICATIONS

This application claims priority under 35 U.S.C. §119(e) to U.S. Provisional Patent Application No. 61/543,885, filed Oct. 6, 2011, and entitled “FREQUENCY MULTIPLEXED SUPERCONDUCTING NANOWIRE SINGLE PHOTON DETECTORS,” which is incorporated herein by reference in its entirety for all purposes.

### GOVERNMENT SPONSORSHIP

This invention was made with government support under Contract No. HR001-10-C-0159 awarded by the Defense Advanced Research Projects Agency. The government has certain rights in the invention.

### FIELD OF INVENTION

Systems, articles, and methods related to nanowire-based detectors are generally described.

### BACKGROUND

Photon detectors are an integral part of many types of systems. In general, photon detectors convert photons into readable electrical signals, and are used in a variety of detectors and sensors in communications and computing systems, astronomy, and other fields. In many applications, information is encoded and transmitted in a signal made up of photons. Efforts to increase the amount of information transmitted and received in such signals often involve increasing the sensitivity and/or speed of photon detectors that detect the photons.

The use of nanowires in photon detectors has been the subject of research. In many nanowire-based detectors, one or more nanowires are positioned on a substrate toward which photons are directed. Individual photons can couple with the nanowire(s) upon contact, producing a detectable signal. Often, such devices are designed to interact with a very small amount of signal energy (e.g., single photons).

Superconducting nanowire single photon detectors (SNSPDs) are devices that use low-temperature meandering nanowires, which may be on the order of 100 nm or less wide, covering a small area on a planar substrate. By current-biasing the nanowires close to their superconducting critical current, they become very sensitive to the absorbed energy of individual photons. Even a single incident photon which is absorbed in the nanowire temporarily creates a region of non-superconductance, or “hot spot,” in the otherwise superconducting wire. This hot spot momentarily alters the electrical properties of the nanowire, until the nanowire resets itself to become superconducting again.

### SUMMARY OF THE INVENTION

The inventors have recognized and appreciated techniques that may be used to improve the efficiency of reading out data from multiple photon detectors. Such techniques may provide improved high speed, high density photon detection systems at lower costs. These techniques may be used together, separately, or in any suitable combination in optical systems using superconducting nanowire photon detectors, such as SNSPDs, or other high-sensitivity photon detectors.

Some aspects relate to a photon detection system comprising an array of resonant cells, each resonant cell comprising a photon detector. The array of resonant cells may be coupled to a common output line. Each resonant cell may comprise a nanowire, and each of the plurality of resonant cells may be configured to provide a different resonant frequency. A frequency detector may be coupled to the output line, and may be configured to detect on the output line transient responses of the plurality of resonant cells.

Some aspects relate to a method of receiving information with a photon detection system. The photon detection system may comprise a plurality of resonant cells, each of the plurality of resonant cells having a different resonant frequency. The method may comprise exposing the photon detection system to a source of photons. Resonant signals within resonant cells may be excited in resonant cells of the plurality of resonant cells by the photons. The method may also comprise providing an output based on at least one transient response detected at an output of a resonant cell of the plurality of resonant cells. Each of the at least one detected transient response may correspond to a resonant frequency of a resonant cell.

Some aspects relate to at least one computer-readable storage medium comprising computer executable instructions that, when executed by a computing device, perform a method. The method may comprise receiving a signal from a photon detection system. The method may also comprise computing a position based on a change in amplitude of at least one frequency component of the signal. The method may further comprise computing a time of initiation of the change in amplitude of the at least one frequency component of the signal.

The foregoing is a non-limiting summary of the invention. Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a schematic illustration of an exemplary optical communication system, in accordance with some embodiments;

FIG. 2A is a schematic illustration of a photon detection system, in accordance with some embodiments;

FIG. 2B is a schematic illustration of a photon detection system, in accordance with some alternative embodiments;

FIG. 2C is a schematic illustration of a photon detection system comprising an AC input source, in accordance with some alternative embodiments;

FIG. 2D is a schematic illustration of a photon detection system comprising an AC input source, in accordance with some alternative embodiments;

FIG. 2E is a schematic illustration of a photon detection system comprising an AC input source, in accordance with some alternative embodiments;

FIG. 3A is a schematic illustration of a resonant cell, in accordance with some embodiments;

FIG. 3B is a schematic illustration of a resonant cell, in accordance with some alternative embodiments;

FIG. 4A is a plan view of a superconducting nanowire photon detector coupled in parallel with a capacitor, in accordance with some embodiments;

FIG. 4B is a schematic illustration of an equivalent circuit model of the superconducting nanowire photon detector coupled in parallel with the capacitor shown in FIG. 4A;

FIG. 4C is a plan view of a superconducting nanowire photon detector coupled in series with a capacitor, in accordance with some embodiments;

FIG. 4D is a schematic illustration of an equivalent circuit model of the superconducting nanowire photon detector coupled in series with the capacitor shown in FIG. 4C;

FIG. 5A is a sketch of a readout signal as a function of time, in accordance with some embodiments;

FIG. 5B is a sketch of a readout signal as a function of time, in accordance with some alternative embodiments;

FIG. 6A is a sketch conceptually illustrating frequency filtering of an AC input source with multiple frequency components by an array of resonant cells, in accordance with some embodiments;

FIG. 6B is a sketch conceptually illustrating frequency filtering of an AC input source with multiple frequency components by an array of resonant cells, in accordance with some alternative embodiments;

FIG. 7 is a flow chart of an exemplary method of receiving information with a photon detection system, in accordance with some embodiments; and

FIG. 8 is a schematic illustration of a representative computing device on which some embodiments may operate.

### DETAILED DESCRIPTION

The inventors have recognized and appreciated that reading out data from a large array of photon detectors, particularly photon detectors based on superconducting wires, can be costly and inefficient due to bias electronics and readout electronics that scale with the size of the array. Such costs and inefficiencies can limit the size of arrays in practical photon detection systems, thus imposing a constraint on the amount of information conveyed in the signals received by the photon detectors.

The inventors have recognized and appreciated that various techniques may be used, either separately or in any suitable combination, to improve approaches for obtaining data using photon detectors. For example, the photon detectors may be inductive nanowire-based detectors, which can be used for detection in, for example, single-photon detectors. In some embodiments, these techniques may be used with superconducting nanowire photon detectors, such as superconducting nanowire single photon detectors (SNSPDs).

Such techniques for improving the efficiency of photon detection may entail providing a photon detection system that couples a plurality of photon detectors to a single readout line, and provides on that readout line a signal that can be used to discriminate both a time and a location of arrival of a photon, by determining which of the plurality of photon detectors interacted with the photon. Such techniques may allow for multiple photon detectors to share a common set of readout electronics, thus conserving cost and space in the photon detection system.

By utilizing both the time and the location of photon arrivals, the total amount of information received may be as large as a product of the amount of information transmitted in each of the spatial component and time component associated with detection of a photon. While information may be transmitted in only the timing or only the position of photon arrivals, the amount of information transmitted solely through timing or position may be limited. For example, increasing timing information may be limited by difficulties in achieving finer resolution in measuring photon arrivals, while increasing positional information may be limited by the size of the photon detector array. By combining timing information with spatial information, a multiplicative increase in received information can be achieved as compared to using either technique individually.

The inventors have further recognized and appreciated techniques for improving the resolution of time measurements of photon arrivals. In some embodiments, the timing of photon arrivals may be detected based on an initial pulse on the readout line. When information is encoded in both the timing and location of photon arrivals, the timing information may first be detected in the initial pulse, before the location information is decoded. This may enable faster resolution of timing information. In some embodiments, this may also enable hierarchical reception of information, for example, by first receiving a first level of information (e.g., coarse or important information) through the time component and subsequently receiving a second level of information (e.g., refined or additional information) through the location component.

In some embodiments, a faster resolution of time of detection of a photon, combined with a multiplicative increase in information and more efficient re-use of electronics, may result in photon detection systems that provide reduced delay and increased information throughput at a reduced size and cost.

The photon detectors used in such systems may comprise nanowires that occupy a small area on a planar substrate. In some embodiments, the photon detectors may be SNSPDs. In some embodiments, each nanowire may be inductive and may be arranged, in conjunction with a capacitive component, to form a resonant cell. A plurality of resonant cells may be coupled to an output line. Each resonant cell may have a unique resonant frequency. However, the resonant characteristics of a cell may change as a result of a photon interaction with the resonant cell. This change may be temporary such that the change triggers a transient response in a signal line connected to the output of a resonant cell.

These transient responses will occur at times correlated with the arrival of a photon at the resonant cell. Accordingly, detecting a time of transient response can indicate a time of arrival of a photon or photons. Determining the time of arrival of a photon may be used in ways that depend on the nature of the system using the photon detector. For example, in a communication system in which the photon detector is used to receive a signal modulated to convey information, the time of arrival of the photon may be used to decode some of the modulated information.

In addition, the transient response will have a frequency component that depends on which of the resonant cells a photon interacted with. Determining which of the resonant cells interacted with a photon provides information about the location of arrival of the photon. In a receiver system in which a received signal is spatially modulated to convey information, determining a frequency component of a transient response indicates which resonant cell a photon interacted with, which in turn provides information about the location of the photon from which the modulating information can be recovered.

In some embodiments, the speed of information resolution may be improved by separately determining the timing of a transient response from determining a frequency component of the transient response. Detecting a time may be performed with less delay than detecting a frequency component. As such, partial information may be received sooner as compared with using frequency analysis alone.

The combination of frequency modulating and spatial modulating, via determining timing and frequency parameters of a signal, may enable efficient use of electronics to readout signals from multiple photon detectors. To determine these parameters, a frequency detector may be coupled to the output line to detect transient responses from any of the plurality of resonant cells.

Based on the transient response, the frequency detector may indicate both a frequency and a time of initiation of the transient response. In some embodiments, a digital code generation circuit may be coupled to the frequency detector. The digital code generation circuit may generate a digital code representing a combination of a value selected based on the detected frequency component and a value indicative of the time of initiation of the transient response.

Depending on the configuration of the resonant cells, the transient response may comprise either an increase or a decrease in amplitude of a frequency component in an output signal. The frequency of that component may coincide with a resonant frequency of one of the resonant cells. For example, an arrival of a photon may induce excitation of a frequency component at the readout line. Alternatively, a photon arrival may induce or prevent absorption or reflection of a frequency component such that the frequency content of a signal on the readout line changes in a measurable way. Regardless of the exact nature of the transient response, the transient response may indicate both an initiation time of a transient response and a resonant frequency of a resonant cell with which a photon interacted.

In some embodiments, the transient response may comprise multiple features, any or all of which may be detected to gather information about a photon interacting with the photon detector. In some embodiments, a transient response may include at least two pulses. A first pulse may indicate a time of initiation of the transient response, when a photon strikes one of the resonant cells. The second pulse may be used to detect a frequency component, indicating the resonant frequency of the resonant cell excited by a photon. The detected frequency component may then be used to determine which resonant cell received the photon, thereby indicating the location of the photon.

In some embodiments, each resonant cell may comprise an inductive nanowire arranged in parallel with a capacitor. Such a resonator configuration may be called a “parallel-resonator resonant cell.” The resonant frequency of the resonant cell may be determined by the inductance (which is influenced by length) of the nanowire and/or the value of the capacitor. Alternatively, in some embodiments, a resonant cell may have an inductive nanowire arranged in series with a capacitor. Such a resonator configuration may be called a “series-resonator resonant cell.”

In some embodiments, the nanowires in each resonant cell may be superconducting. In some embodiments, there may be a DC bias source coupled to each resonant cell. The DC bias source may be configured to maintain the nanowire in the resonant cell at just below a superconducting threshold. Such biasing may be achieved using techniques known in the art. Arrival of a photon may drive the nanowire above the threshold, thus temporarily altering superconductive properties of the nanowire. The change in the superconducting properties can in turn change the resonant characteristics of the resonant cell and cause a transient response on the readout line.

In some embodiments, the resonant cells may be configured such that the change in resonant characteristics may entail excitation of the resonant cell at its resonant frequency. As a result, a signal at a resonant frequency may be coupled from an excited resonant cell to the frequency detector. Alternatively or additionally, the change in resonant characteristics of a cell may change the Q factor of the resonant cell because of an increase in resistance in the cell, creating a measurable impact on an AC source applied to the resonant cell. In some embodiments, the AC source may be simultaneously provided to all of the resonant cells. Such an AC source may contain multiple frequency components, or tones, that are matched to the resonant frequencies of the cells. Any change in the frequency response of a resonant cell, for example due to photon absorption, may change the readout of the corresponding frequency component from the AC source.

Accordingly, in some embodiments, in addition to the DC bias source, there may be an alternating current (AC) input source, providing a signal that can be changed when the resonant frequency of a resonant cell changes. Resonant cells, depending on their configuration as resonant cells in parallel with each other or resonant cells in series with each other, will preferentially pass or block frequency components at or near the resonant frequency of the cell. When the resonant characteristics of a resonant cell change, this change may be most visible with respect to frequency components of an AC source that are at or near the resonant frequency of the resonant cell with resonant characteristics change.

For example, in some embodiments, an arrival of a photon at a resonant cell may change characteristics of a resonant cell such that, instead of a frequency component near the resonant frequency of that cell passing from the AC source to the frequency detector with little attenuation, significant attenuation of that frequency may occur, leading to reduced amplitude at the readout line for that resonant frequency. Alternatively, in some embodiments, frequency components of the AC input sources may be prevented from reaching the output line by their respective resonant cells when the nanowires in those cells are in their un-excited states. Arrival of a photon may cause one of the resonant cells to change its resonant characteristics such that a frequency component corresponding to the resonant frequency of that cell may reach the frequency detector, causing an increase in measured amplitude for that resonant frequency.

The specific impact at the output of a resonant array may depend on how the resonant cells are connected together into an array between the AC source and an output to which a frequency detector is connected. For example, resonant cells may be connected to the output line to provide a shunt path to ground. Depending on the resonant characteristics of the cells, they will either shunt to ground frequency components corresponding to their resonant frequencies or allow those frequency components to pass on to the output. Alternatively, the resonant cells may be coupled in line between with the AC source and frequency detector such that, depending on the resonant characteristics of the cells, they will either pass frequency components at their resonant frequencies or block them from reaching the frequency detector by attenuating or reflecting those frequencies.

In some embodiments, series-resonator resonant cells may be coupled to each other in parallel. In some embodiments, parallel-resonator resonant cells may be coupled to each other in series. Though, it should be appreciated that any configuration of resonant cells that results in frequency components at the resonant frequencies of the cells either reaching or not reaching the frequency detector, depending on the conducting state of the nanowires in the resonant cells, may be used.

In some embodiments, analyzing the transient response on the readout line may entail analyzing one or more frequency components of a signal on that line. In some embodiments, this may entail using a frequency detector to analyze the frequency content of a signal. For example, the frequency detector may provide an output code that is proportional to the frequency of an input signal. In some embodiments, a digital frequency discriminator, or DFD, may be used. Though, a frequency discriminator may be implemented in other forms, such as using analog circuitry. In general, however, the frequency detector may utilize any appropriate technique to analyze the frequency content of the readout signal.

The systems, articles, and methods described herein can be used in a variety of applications, for example, to produce highly sensitive photon counters. Such counters can be useful in the production of cryptographic devices (e.g., fiber-based quantum key distribution systems), photon counting optical communication systems, and the like. In some cases, the systems, articles, and methods can be used to produce or as part of a linear optical quantum computer. The embodiments described herein can also be used in the evaluation of transistor elements in large-scale integrated circuits, as the elements emit photons; characterization of the photons and their time of arrival can be used to understand the operation of the circuit, for example. The embodiments described herein may also find use in underwater communications, inter-planetary communications, or any communication system in which ultra-long-range or absorbing or scattering media produce relatively high link losses.

In some cases, circuit components may be fabricated on a chip, and offloaded onto microwave lines for amplification and readout. Superconducting nanowire photon detectors may operate at telecom wavelengths, making them suitable for high-speed communications over long-distance telecom optical fibers. Using both spatial multiplexing and time multiplexing may increase the available bandwidth in such telecom systems. For example, on an array of size 1,024 resonant cells, the spatial position of each photon represents 10 bits of information. The amount of information communicated by a photon may be multiplied if time modulation is also used.

In some cases, the methods described herein can be used with superconducting nanowire single-photon detectors (SNSPDs). The basic functionality of SNSPDs are described, for example, in “Electrothermal feedback in superconducting nanowire single-photon detectors,” Andrew J. Kerman, Joel K. W. Yang, Richard J. Molnar, Eric A. Dauler, and Karl K. Berggren, Physical Review B 79, 100509 (2009). Briefly, a plurality of photons can be directed toward a superconducting nanowire (e.g., a niobium nitride (NbN) nanowire). A portion of the photons can be absorbed by the nanowire, to which a bias current is applied. When an incident photon is absorbed by the nanowire with a bias current slightly below the critical current of the superconducting nanowire, a resistive region called hot-spot is generated, which can yield a detectable voltage pulse.

In many systems and devices employing photon-detecting nanowires (e.g., where the nanowire is being used in an SNSPD), it can be beneficial to design the nanowire such that it is narrower than 100 nm and as thin as 4 to 6 nm to allow for effective photon detection. In nanowires used to detect infrared radiation, for example, these nanowire widths are an order of magnitude narrower than the Rayleigh diffraction limit of the infrared radiation. Therefore, it is often beneficial to design the nanowire (or a plurality of nanowires) such that they cover a relatively large amount of area.

The term “electrically superconductive material,” is given its accepted meaning in the art, i.e., a material that is capable of conducting electricity in the substantial absence of electrical resistance below a threshold temperature. One of ordinary skill in the art would be able to identify electrically superconductive materials suitable for use with the invention.

The electrically superconductive material can be formed using any suitable method. In some cases, the electrically superconductive material can be provided as an as-grown film on a substrate. In some instances, the electrically superconductive material can be formed via electron-beam deposition or sputter deposition. In some embodiments, a relatively thin layer of electrically superconductive material can be provided. For example, in some embodiments, the layer of electrically superconductive material can have an average thickness of less than about 20 nm, less than about 10 nm, less than about 5 nm, between about 2 nm and about 20 nm, between about 2 nm and about 10 nm, or between about 4 nm and about 6 nm. One of ordinary skill in the art would be capable of measuring the thicknesses (and calculating average thicknesses) of thin films using, for example, a transmission-electron microscope.

A variety of electrically superconductive materials are suitable for use in the embodiments described herein. For example, in some embodiments, the electrically superconductive material can comprise niobium (Nb). In some cases the electrically superconductive material can be niobium nitride (NbN), niobium metal, niobium titanium nitride (NbTiN), or a combination of these materials. Though, it should be appreciated that the invention is not limited to a particular superconductive materials, and other suitable materials may be used, such as tungsten silicide, which is a material known in the art. In some cases, the electrically superconductive material can be patterned to form a nanowire, as discussed in more detail below. The electrically superconductive material (e.g., in the form of a nanowire) can be used, in some embodiments, as a medium in or on which photons are absorbed (e.g., when used in a photon detector).

A variety of substrates are suitable for use in the systems, articles, and methods described herein. In many embodiments, the substrate is formed of an electrically insulating material. The substrate can be capable, in some instances, of transmitting at least a portion of at least one wavelength of electromagnetic radiation. For example, the substrate might be substantially transparent to at least one wavelength of electromagnetic radiation (e.g., at least one wavelength, as measured in a vacuum, of infrared radiation). In embodiments where the nanowire is constructed and arranged to detect photons, the substrate can be formed of a material that is capable of transmitting at least a portion of the photons of a predetermined wavelength that the detector is constructed and arranged to detect. The use of a transparent substrate can allow one to employ opaque materials (e.g., metals) on the side of the detector opposite the substrate while maintaining a pathway by which photons can reach and be absorbed by the nanowire. Examples of materials suitable for use in the substrate include, but are not limited to, sapphire, magnesium oxide, silicon nitride, and silicon dioxide.

The term “nanowire,” as used herein, is used to refer to an elongated structure that, at any point along its longitudinal axis, has at least one cross-sectional dimension (as measured perpendicular to the longitudinal axis) of less than 1 micron. In some embodiments, a nanowire can have, at any point along its longitudinal axis, two orthogonal cross-sectional dimensions of less than 1 micron. An “elongated” structure is a structure for which, at any point along the longitudinal axis of the structure, the ratio of the length of the structure to the largest cross-sectional dimension perpendicular to the length at that point is greater than 2:1. This ratio is termed the “aspect ratio.” In some embodiments, the nanowire can include an aspect ratio greater than about 2:1, greater than about 5:1, greater than about 10:1, greater than about 100:1, or greater than about 1000:1.

The nanowire can have any suitable width. Generally, the width of the nanowire at a given point along the longitudinal axis of the nanowire is measured as the largest cross-sectional dimension of the nanowire parallel to the plane of the material on which the nanowire is positioned and perpendicular to the longitudinal axis of the nanowire. For example, in cases where the nanowire is positioned on or proximate a substrate, the width of the nanowire is generally measured in a direction parallel to the plane defined by the substrate. In some embodiments, the maximum width of the nanowire (i.e., the maximum of the widths along the longitudinal axis of the nanowire) can be less than about 500 nm, less than about 250 nm, less than about 100 nm, less than about 25 nm, between about 10 nm and about 500 nm, between about 25 nm and about 500 nm, between about 50 nm and about 250 nm, or between about 75 nm and about 125 nm. In some instances, the average width of the nanowire (i.e., the average of the widths as measured along the length of the nanowire) can be less than about 500 nm, less than about 250 nm, less than about 100 nm, between about 25 nm and about 500 nm, between about 50 nm and about 250 nm, or between about 75 nm and about 125 nm.

In some embodiments, the nanowire can include a relatively consistent width. For example, the width of a nanowire can be within about 20%, within about 10%, within about 5%, or within about 1% of the average width of the nanowire over at least about 50%, at least about 75%, at least about 90%, at least about 95%, or at least about 99% of the length of the longitudinal axis of the nanowire.

In some embodiments, the nanowire can include a plurality of elongated portions (whether straight or curved) that can be substantially equally spaced. In some cases, the substantially equally spaced elongated portions (whether straight or curved) can be separated by distances (as measured along a straight line perpendicular to the lengths of and/or tangents of each of the two elongated portions) that are within about 90% of the average distance between the two portions along at least about 90% of the length of the portions. In some embodiments, the distances between the two substantially equally spaced elongated portions can be within about 90%, within about 95%, or within about 99% of the average distance between the two portions along at least about 90%, along at least about 95%, or along at least about 99% of the lengths of the portions, wherein the elongated portions have aspect ratios of greater than about 5:1, greater than about 10:1, greater than about 100:1, or greater than about 1000:1. A nanowire can include, in some embodiments, at least 3, at least 4, at least 5, or more elongated portions meeting the criteria outlined above.

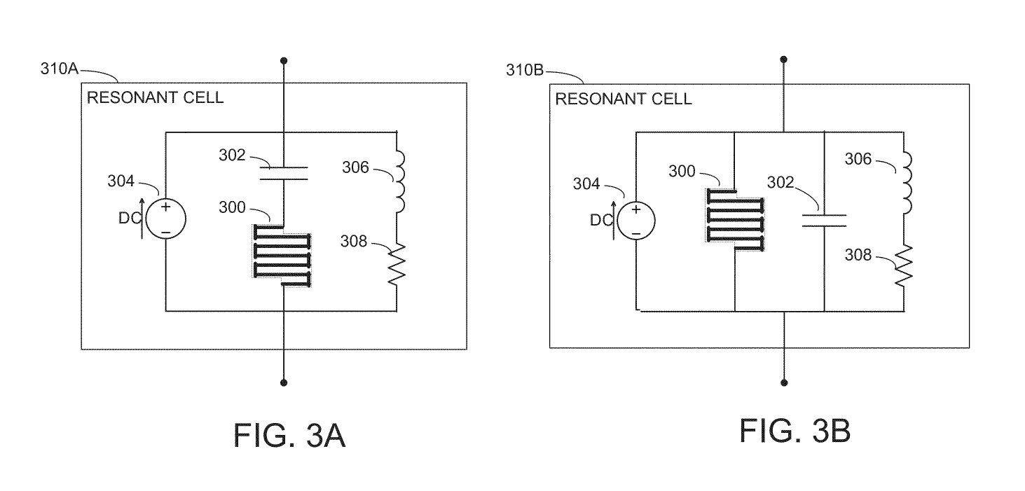

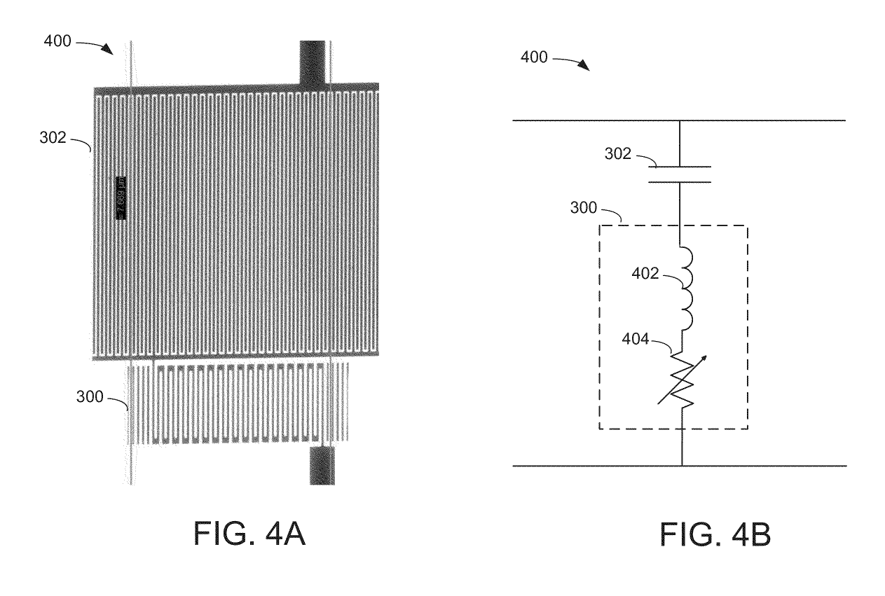

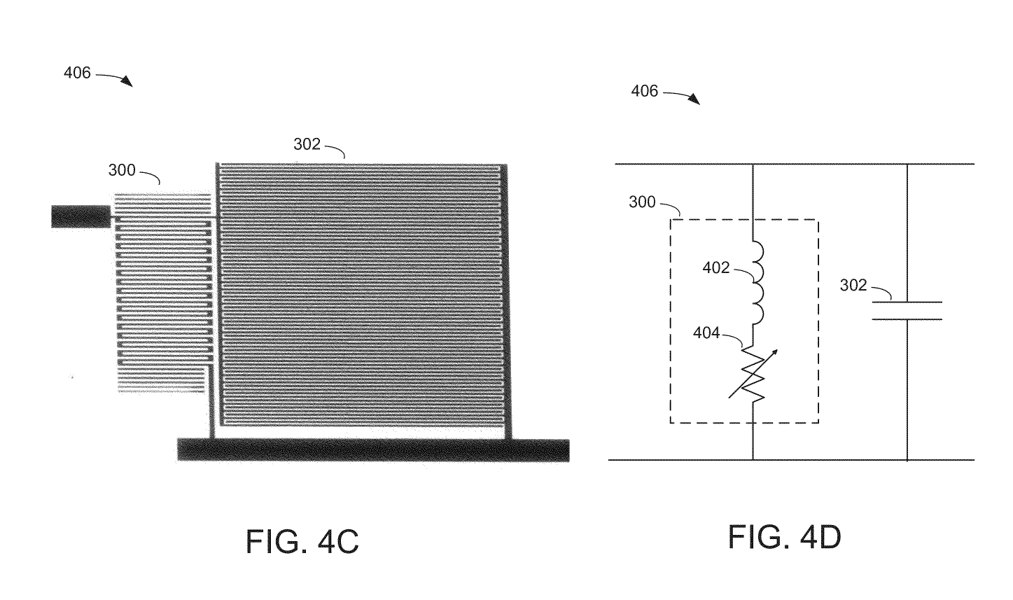

In some cases, the plurality of elongated, substantially equally spaced portions of the electrically superconductive material can be substantially parallel. The plurality of elongated portions can be arranged, in some embodiments, in a side-by-side manner (i.e., a straight line perpendicular to the lengths and/or tangents of the elongated portions intersects each of the plurality of elongated portions). Some examples are illustrated in FIGS. 3A, 3B, 4A, and 4C. The plurality of elongated portions can be connected by portions of electrically superconductive material proximate the ends of the elongated portions to form a serpentine nanowire. The serpentine nanowire can include a regularly repeating pattern of turns that form multiple portions (which can be substantially parallel) spaced at a regular interval.

While FIGS. 3A, 3B, 4A, and 4C illustrate some possible embodiments in which a single nanowire is formed in a serpentine pattern, it should be understood that other patterns can be formed. For example, a plurality of nanowires can be formed. In some embodiments, a plurality of nanowires, not monolithically integrally with each other (i.e., connected via the same electrically superconductive material during a single formation step), can be formed as a series of substantially parallel nanowires arranged in a side-by-side manner. In such cases, the nanowires can be connected, in series or in parallel, using a different electrically superconductive material (e.g., formed on the substrate), an electrically conductive material (e.g., metals such as gold, silver, aluminum, titanium, or a combination of two or more of these which can be, for example, formed on the substrate), and/or using a off-substrate circuitry. In cases where multiple substantially parallel nanowires are used, the period of the plurality of nanowires is defined in a similar fashion as described above with relation to the serpentine nanowire.

In still other embodiments, the plurality of elongated, substantially equally spaced portions of electrically superconductive material can include one or more curves. For example, the plurality of elongated, substantially equally spaced portions can be substantially concentric, in some cases. In some embodiments, portions of the nanowire may be formed in the shape of a spiral.

In some embodiments, the nanowire (or plurality of nanowires) can include a relatively large period. For example, the period between elongated substantially equally spaced portions of the nanowire can be at least about 250 nm, at least about 500 nm, at least about 600 nm, between about 250 nm and about 800 nm, between about 500 nm and about 700 nm, or between about 550 nm and about 650 nm, in some embodiments. In some cases, the period can depend on the index of refraction of the substrate material and/or the wavelength of electromagnetic radiation to which the detector is designed to be exposed. For example, as the wavelength (as measured in a vacuum) of the detected electromagnetic radiation is increased, it can be desirable to increase the period. In some cases, as the index of refraction of the substrate material is increased, it may be desirable to decrease the period. In some embodiments, the period of substantially equally spaced portions of the nanowire can be between about 0.45(λ/n) and about 0.9(λ/n), between about 0.55(λ/n) and about 0.8(λ/n), between about 0.60(λ/n) and about 0.75(λ/n), or between about 0.66(λ/n) and about 0.69(λ/n), wherein λ is the wavelength of electromagnetic radiation (as measured in a vacuum) to which the detector is constructed and arranged to be exposed, and n is the index of refraction of the substrate material. Nanowires with relatively large periods can be useful in forming photon detectors with relatively large surface areas, while maintaining reasonable efficiencies and speeds.

The photon detectors described herein can be constructed and arranged to detect wavelengths of electromagnetic radiation that fall within specified ranges. For example, in some cases, a photon detector can be constructed and arranged to detect infrared electromagnetic radiation (e.g., infrared electromagnetic radiation with a wavelength between about 750 nm and about 10 micrometers, as measured in a vacuum). In some cases, the photon detector can be constructed and arranged to detect visible light (i.e., wavelengths of between about 380 nm and about 750 nm, as measured in a vacuum). In some cases, the photon detector can be constructed and arranged such that, during operation, it can be tuned to detect a predetermined range of wavelengths of electromagnetic radiation (e.g., a range with a width of less than about 1000 nm, less than about 100 nm, less than about 10 nm, between about 0.1 nm and about 1000 nm, between about 0.1 nm and about 100 nm, between about 0.1 nm and about 10 nm, or between about 0.1 nm and about 1 nm, each range as measured in a vacuum).

The photon detectors described herein can have various sizes of active areas. In some embodiments, a photon detector can have an active area of at least about 9 square microns, at least about 25 square microns, at least about 75 square microns, at least about 150 square microns, between about 9 square microns and about 250 square microns, or between about 9 square microns and about 100 square microns.

In addition, a photon detector can operate with a relatively small reset time (i.e., the detector can operate at a relatively fast speed). As used herein, the “reset time” of a detector is measured as the time one must wait between a detection and the point at which the detector efficiency returns to at least 90% of its original efficiency.

A variety of materials and methods can be used to form articles (e.g., photon detectors) and systems described herein. In some cases, one or more components can be formed using MEMS-based microfabrication techniques. For example, various components can be formed from solid materials, in which various features (e.g., nanowires, gratings of electrically conductive material, layers of electrically insulating material, and the like) can be formed via micromachining, film deposition processes such as spin coating and chemical vapor deposition, laser fabrication, photolithographic techniques, etching methods including wet chemical or plasma processes, and the like.

One of ordinary skill in the art would understand how to connect the devices described herein to external devices (e.g., an RF coaxial readout, a lens coupled fiber, etc.) for use in practice. For example, electrical contacts can be made to the electrically superconductive material (e.g., the electrically superconductive nanowire) by fabricating electrically conductive contact pads connected to the ends of the electrically superconductive material. In some embodiments, the devices (e.g., photon detectors) described herein can be constructed and arranged to be used at very low temperatures (e.g., less than about 10 K, less than about 5 K, or less than about 3 K). One of ordinary skill in the art would be capable of designing the systems and articles described herein such that stable electrical communication could be made at these very low temperatures.

The terms “electrically insulating material,” “electrically conductive material,” and “semiconductor material” would be understood by those of ordinary skill in the art. In addition, one of ordinary skill in the art, given the present disclosure, would be capable of selecting materials that fall within these categories while providing the necessary function to produce the devices and performances described herein. For example, one of ordinary skill in the art would be capable of selecting a material that would be capable of providing proper electrical insulation between an electrically superconductive material and a relatively electrically conducting material in order to, for example, prevent electron transfer between those two materials. In some embodiments, an electrically conductive material can have an electrical resistivity of less than about 10⁻³ ohm·cm at 20° C. The electrically insulating material can have, in some instances, an electrical resistivity of greater than about 10⁸ ohm cm at 20° C. In some instances, a semiconductor material can have an electrical resistivity of between about 10⁻³ and about 10⁸ ohm·cm at 20° C.

The speed of SNSPDs quantifies how fast the detector can count photons, and can be defined as 1/τ, where t is the reset time (defined above). The speed of the detector may depend on the kinetic inductance, Lₖ of the detector. The recovery of the bias current, (and therefore, the detection efficiency), may be determined by the kinetic inductance. For example, a 90%-efficiency recovery time may be approximately 1 ns to 5 ns.

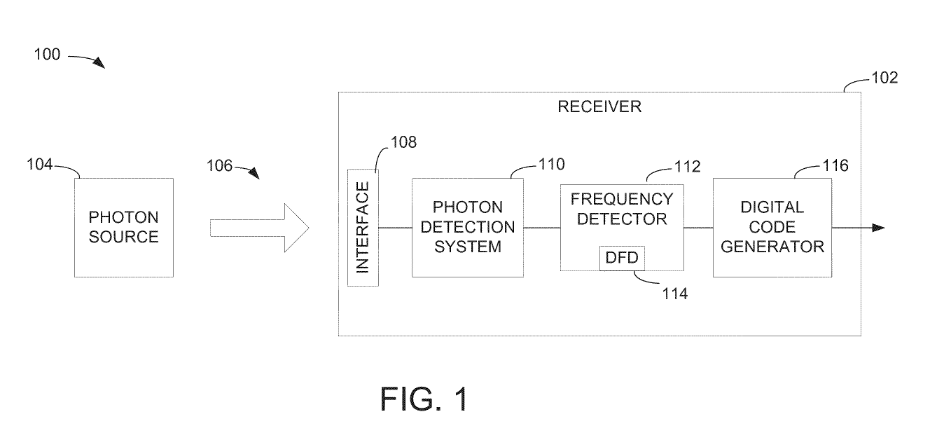

FIG. 1 is a schematic illustration of an exemplary optical communication system 100, in accordance with some embodiments. An optical receiver 102 may be configured to receive signals from a photon source 104. The photon source 104 may be any suitable source of photons, such those used in optical transmitters in fiber optics or free-space optics. Though, it should be appreciated that the photon source need not be a mechanical transmitter, and may be an object which is to be imaged, for example by a camera or detector, as is known in fields such as astronomy or photography.

The photon source may emit photons which travel through an optical communication medium 106. The nature of the photon source is not critical to the invention, and photons emitted by that source may have any suitable frequency. For example, sensitive detectors as described herein may be used to detect photons in the infrared range or higher frequency photons.

The optical communication medium 106 may be a component that guides the photons. Examples of such medium include a fiber, waveguide, or a coupler. Alternatively, in some embodiments, the optical communication medium 106 may be free space. Regardless of the exact nature of the photon source 104 and the optical communication medium 106, the optical receiver 102 may receive one or more photons at different times.

The reception of photons may, in some embodiments, be performed via an interface 108. The interface may allow coupling between the receiver 102 and the optical communication medium 106, which may be a fiber optic cable or a waveguide. Alternatively or additionally, the interface may comprise lenses or other components that facilitate reception of photons from the communication medium 106 and coupling them to photon detection system 110.

A photon detection system 110 may be configured to detect the arrival of photons. In some embodiments, the photon detection system 110 may comprise an array of photon detectors, each configured to detect the arrival of one or more photons. In some embodiments, arriving photons may be directed by the photon source, or interface, to a particular detector in the array of photon detectors. The location of the particular photon detector in the array that detects a photon may represent information about the incident signal. By detecting which photon detector interacted with a photon, the communication system may utilize spatial multiplexing and/or spatial encoding.

The location of the photon detector that interacts with a photon may be identified by a transient response emitted by that photon detector. In some embodiments, the transient response may include a frequency component that is unique to the detecting photon detector. By discriminating the frequency component in the transient response, the location of the photon arrival may be determined. In such an example, frequency detection may be used to enable spatial multiplexing.

In some embodiments, a frequency detector 112 may be used to detect one or more frequency components in an output signal of the photon detection system 110. The frequency detector may utilize any suitable technique to analyze the frequency components of a signal, as is known in the art. For example, the frequency detector 112 may use a digital frequency discriminator (DFD) 114, which converts a frequency into a voltage level. Such a frequency discriminator may be implemented in any suitable way, such as using a signal processing chip or a Programmable Gate Array (such as an FPGA) programmed for frequency detection.

Regardless of the exact technique used to analyze the frequency components, the frequency detector 112 may, in some embodiments, be configured to detect a frequency component in a transient response at the output of the photon detection system 110. Based on the detected frequency component, in some embodiments, the frequency detector 112 alternatively or additionally may indicate a time of initiation of the transient response, in addition to the detected frequency component. The initiation time may convey additional information about the incident signal.

The location of photon arrival and the frequency component may be converted to information, here in digital form, by a digital code generation circuit 116. For example, the digital code generation circuit 116 may be configured to generate a digital code representing a combination of a value indicative of a time of initiation of the transient response and a value selected based on the detected frequency component in the transient response. The amount of information decoded by the digital code generation circuit 116 may be as large as a product of the amount of information represented in each of the time and frequency components. In some embodiments, this may be used to achieve nearly-multiplicative increase in received information from the same photon source, as compared to using either time or spatial multiplexing alone.

The photon detection system 110 may comprise a plurality of resonant cells. Each resonant cell may be configured to provide a specific frequency response that will create different outputs upon a photon absorption. The resonant cells may be arranged in an array, although it should be appreciated that any suitable layout of resonant cells may be used within the photon detection system 110.

The resonant cells may be configured in a variety of ways to achieve both time and space encoding. Both the interconnection between resonant cells, as well as the structure within each resonant cell itself, may be varied to achieve different embodiments. The exact nature of the inter-cell interconnections and the intra-cell structures may determine characteristics of the output of the photon detection system when converting photon arrivals to electrical output signals. However, digital code generator 116 may be configured based on the configuration of the resonant cells so that it outputs a digital code representing information conveyed by the timing and/or location of a photon.

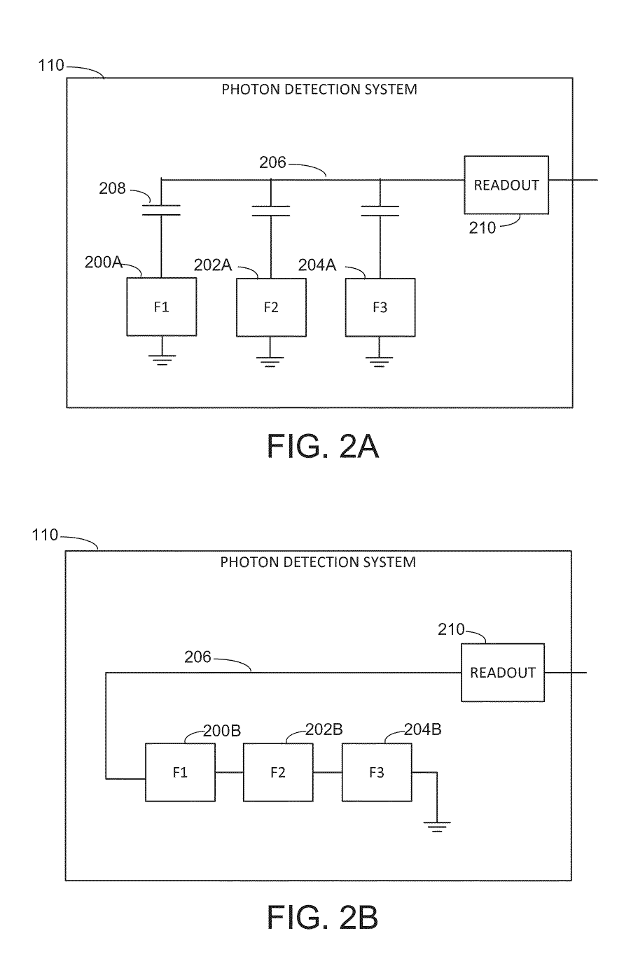

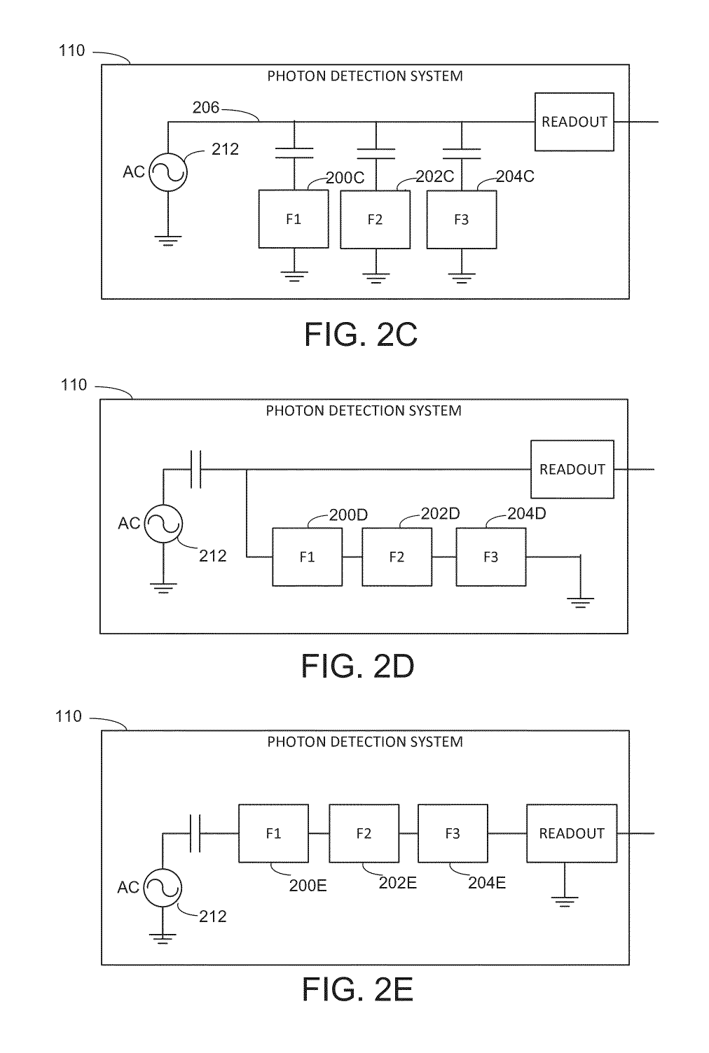

FIGS. 2A-2E illustrate examples of configurations for interconnecting multiple photon detectors within a photon detection system 110, according to some embodiments. Subsequently, FIGS. 3A-3B will illustrate different ways of configuring the internal connections within each photon detector. It should be appreciated, however, that the photon detection system 110 is not limited to these examples, and may be configured in various combinations or variations of these examples to achieve separated discrimination of a time component and spatial component of photon arrivals. In the embodiments illustrated in these figures, each of the resonant cells is designed with a different resonant frequency such that a specific resonant cell that interacted with a photon may be determined based on a frequency measurement.

FIG. 2A is a schematic illustration of an exemplary configuration of a photon detection system 110. In this example, three photon detectors are illustrated, which may be, for example, resonant cells 200A, 202A, and 204A. It should be appreciated that three resonant cells are shown for simplicity. Any suitable number of resonant cells may be used in a photon detection system 110, subject to certain physical limitations.

In the configuration shown in FIG. 2A, the resonant cells 200A, 202A, and 204A may be coupled in parallel to each other on a single readout line 206. The coupling may be achieved by AC coupling components, such as capacitors, one of which is labeled as capacitor 208. In this embodiment, each of the resonant cells 200A, 202A, and 204A may be configured such that, when a photon interacts with the cell, it emits a signal of the resonant frequency of the cell. The readout line 206 may carry, in one signal output, different responses emitted from the resonant cells 200A, 202A, and 204A. The signal may be read by a readout circuit 210, which may be capable of detecting components of different frequencies within the signal. By enabling multiple resonant cells to share a single readout line, the amount of readout electronics 210 may be reduced. In this example, the same readout circuit is used to indicate detection of a photon at any of the resonant cells.

FIG. 2B is a schematic illustration of an example of an alternative configuration of a photon detection system 110, in accordance with some embodiments. In this example, the resonant cells 200B, 202B, and 204B are interconnected in series. Again, they all share a single readout line 206, which is read by a readout circuit 210. As compared to FIG. 2A, this configuration may result in a different output signal at the readout line 206 when a photon is detected by one of the resonant cells, 200B, 202B, or 204B. Nonetheless, a change in frequency components on the readout line 206 may indicate both that a photon interacted with one of the resonant cells and, based on the frequency at which such a change occurs, which of the resonant cells interacted with a photon.

FIGS. 2C-2E illustrate examples of photon detection systems that utilize an AC input source coupled to probe each resonant cell. The AC input source may emit a plurality of frequency components, or tones, matched to the resonant frequencies of the resonant cells. The tones may be filtered at the readout line based on the frequency response characteristics of the array of resonant cells. As such, in the examples of FIGS. 2C-2E, the readout circuit may be viewed as reading out changes in the filtered output of the AC input signals after they are filtered through the array of resonant cells. By comparison, the examples in FIGS. 2A-2B may be viewed as reading out the resonances from within the array of resonant cells, when they are excited by photon absorption. In either scenario, the readout circuitry may be configured to detect transient changes in the readout signal to determine both a time and position of photon arrivals.

FIG. 2C is a schematic illustration of a photon detection system 110 comprising an AC input source 212, in accordance with some alternative embodiments. In this example, the resonant cells 200C, 202C, and 204C are interconnected in parallel with each other and with the AC input source 212, via common readout line 206.

FIG. 2D is a schematic illustration of a photon detection system 110 comprising an AC input source, in accordance with some alternative embodiments. In FIG. 2D, resonant cells 200D, 202D, and 204D are interconnected in series with each other and in parallel with the AC input source 212. In this example, the readout signal is taken before the first resonant cell, in this example, resonant cell 200D.

FIG. 2E is a schematic illustration of a photon detection system 110 comprising an AC input source 212, in accordance with some alternative embodiments. In FIG. 2E, resonant cells 200E, 202E, and 204E are interconnected in series with each other and with the AC input source 212. In this example, the readout signal is taken after the last resonant cell, in this example resonant cell 204E. It should be appreciated that the AC input source 212 may be any suitable source that simultaneously emits a plurality of frequency components, as is known in the art.

FIGS. 3A and 3B are schematic illustrations of two possible embodiments of a resonant cell depicted in FIGS. 2A . . . 2E. FIG. 3A shows an internal configuration within a resonant cell 310A and FIG. 3B shows an internal configuration within a resonant cell 310B. In some embodiments, the resonant cell may comprise a nanowire. The nanowire may be superconducting at low temperatures, as is known in the art. For example, the superconducting nanowire may be SNSPDs.

Superconducting nanowires may act as inductors due to the energy stored in superconducting Cooper pairs. The inductance of a nanowire may depend on various physical properties, such as the length and thickness of the nanowire. In some embodiments, the resonant cells in an array may have identically-inductive superconducting nanowires that are paired with different values of capacitors, resulting in resonant cells in the array with different resonant frequencies. Alternatively or additionally, either one or both of the nanowire inductance and value of capacitance may be varied to achieve unique resonant frequencies in different resonant cells. In some embodiments, the resonant frequencies may be in the gigahertz range. Though, it should be appreciated that the range of resonant frequencies used is not critical to the invention.

FIG. 3A illustrates a circuit schematic of an embodiment of a resonant cell 310A in which an inductive nanowire 300 is coupled in series with a capacitor 302. Such a configuration may be modeled as a series LC circuit, and may exhibit properties that can be understood using conventional circuit theory. In some embodiments, there may be a DC bias 304 that supplies a bias current through the inductive nanowire 300. The DC bias 304 may be configured such that the current passing through the nanowire 300 is just below a threshold, above which the nanowire 300 is no longer superconducting.

As such, a surge of energy, such as may be supplied by a photon absorption, may cause the nanowire 300 to become non-superconducting. When a photon is absorbed by a nanowire, the energy destroys Cooper pairs, and impedes the flow of current. In some embodiments, the nanowire may be narrow enough such that a significant fraction of Cooper pairs are destroyed in a localized region, causing an entire cross-sectional region of the nanowire to exhibit non-superconducting behavior. This may cause the nanowire to effectively behave as a large resistive element and will momentarily remain in this state until the nanowire returns to its superconducting state.

The altered resistivity of the nanowire 300 may temporarily alter the resonant characteristics of the resonant cell 310A, resulting in a transient response. This transient response may manifest itself at the readout line in different forms, depending on how the resonant cells are interconnected (i.e., FIGS. 2A-2E). The bias current through the momentarily highly resistive nanowire, for example, may generate a voltage pulse that excites a resonant mode of the resonant cell, creating a measurable signal at the resonant frequency of the cell.

In some embodiments, a transient response may include signals generated when the nanowire 300 leaves and returns to superconducting state after a photon absorption. In such embodiments, a single photon absorption may result in a transient response that includes two pulses, or excitations, at the readout line. Either or both of these pulses might be measured.

Alternatively or additionally, the sudden introduction of a large resistance in the cell may substantially lower the Q factor of the resonant cell, meaning that the selectivity of the resonant cell for passing or blocking frequency components at its resonant frequency will momentarily lessen to a substantial degree. If an AC source is providing a signal including a frequency component at the resonant frequency is probing the cell, the effect of that resonant cell on that frequency component of the probing signal will momentarily change, creating a measurable effect. Such an effect may include an increase or a decrease of that frequency component.

The specific effect observed may depend on the configuration of the resonant cells. In some embodiments, a series configuration of resonant cell, such as resonant cell 310A in the example of FIG. 3A, may be used in a resonant cells that are interconnected in a parallel inter-cell configuration, such as the example configurations shown in FIGS. 2A and 2C.

FIG. 3A shows that resonant cell 310A includes damping components including inductance 306 and resistor 308. When the nanowire 300 returns to its superconducting state after a resonance has been excited, the resonant will have a very high Q factor and may tend to ring for a long time. To increase the time between when a resonant cell can produce a distinguishable output signal indicating arrival of a photon, in some embodiments, such damping components may be included. These components may have values that provide decay constant for the resonant signal that is short, but long enough to produce a measurable resonant signal. It should be appreciated that the exact configuration of the damping components is not critical, and the exact value of the components may depend on the detection capabilities of a frequency detector with which the resonant cells are used.

FIG. 3B is illustrates a circuit schematic of an example of an alternative embodiment of a resonant cell 310B, in which an inductive nanowire 300 is coupled in parallel with a capacitor 302. As in FIG. 3A, in steady-state, the DC bias 304 maintains a steady current through the inductive nanowire 300 that is just below a threshold current of superconductivity. A photon detection may result in a large resistance generated in the nanowire inductor 300, which may produce a transient response that changes the frequency response of the resonant cell 200. As with the embodiment of FIG. 3A, damping components, including inductor 306 and resistor 308 may be used.

In some embodiments, a parallel configuration of a resonant cell, such as resonant cell 310B in the example of FIG. 3B, may be used in resonant cells that are interconnected in a series inter-cell configuration, such as the example configurations shown in FIGS. 2B, 2D and 2E.

FIGS. 4A-4C illustrate further details of the structure of a portion of a resonant cell. FIGS. 4A and 4C are images of the planar design of a resonant structure comprising a nanowire 300 and a capacitor 302. FIGS. 4B and 4D are schematics of lumped element circuits for the resonant structure shown in FIGS. 4A and 4C, illustrating an equivalent circuit model.

FIG. 4A is a plan view of a resonant structure 400 comprising a nanowire 300 coupled in series with a capacitor 302, which may be used, for example, in the resonant cell configuration of FIG. 3A. As described previously, the nanowire 300 is arranged in a serpentine pattern, although it should be appreciated that other suitable patterns may be used, such as concentric circles. The nanowire 300 is coupled to a capacitor 302, which may also comprise a nanowire material similar to that of nanowire 300. The capacitor 302 may comprise multiple interlocking “fingers” and the spacing between the interlocked “fingers” may provide capacitance. The particular configuration of capacitor 302, however, is not critical, and may be any suitable configuration, such as any planar design.

FIG. 4B is a schematic illustration of an equivalent circuit model of a nanowire 300 coupled in series with the capacitor 302 as shown in FIG. 4A. In some embodiments, the nanowire 300 may be represented by an equivalent circuit comprising an inductive element 402 and a variable-resistive element 404. The variable resistor 404 may represent the changing resistivity of the nanowire 300 in response to a photon absorption or a return to superconducting state after a photon absorption.

FIG. 4C is an plan view of a resonant structure 406 comprising a nanowire 300 coupled in parallel with a capacitor 302, in accordance with some embodiments. Such configurations may be used, for example, in series-resonant cells such as the example shown in FIG. 3B.

FIG. 4D is a schematic illustration of an equivalent circuit model of a resonant component 406 comprising a nanowire 300 coupled in parallel with the capacitor 302, as in the example of FIG. 4C. As described previously, the nanowire 300 may be modeled as a circuit comprising an inductive element 402 and a variably-resistive element 404. The value of the resistance depends on the superconducting state of the nanowire 300. The combination of the inductive element 402, resistive element 404, and capacitive element 302 forms a parallel RLC resonant structure. The value of resistance 404 impacts the damping factor of the resonance. When the nanowire 300 is not superconducting, the resistance of resistive element 404 is large, and the resonance is highly dampened, only oscillating for a few periods. When the nanowire 300 is superconducting, the resistor 404 is nearly negligible, and the resonant structure 406 may resonate with little dampening and more oscillations.

The resonance that is emitted from a resonant cell may manifest at the readout line in different forms, depending on the interconnections between resonant cells (of which different example were shown in FIGS. 2A-2E).

When a photon arrives at a resonant cell, the photon absorption may be modeled as a large resistance 404 in series with nanowire inductive element 402. Since the nanowire 300 is under a DC current bias, the large resistance will generate a voltage pulse. In some embodiments, this voltage pulse may have a very short rise time on the order of picoseconds, giving it a large spectral bandwidth, which excites the resonant cell it is enclosed in. As an analogy, this may be viewed as a bell ringing due to a mechanical impulse of another object. Once the resonant cell is excited, its unique frequency component, or tone, may be read out, and the photon location may be determined.

Such a technique of “ringing the bell” may be used, for example, in configurations as shown in FIGS. 2A and 2B. In those examples, a photon absorption excites one of the resonant cells and creates a transient response at the readout line.

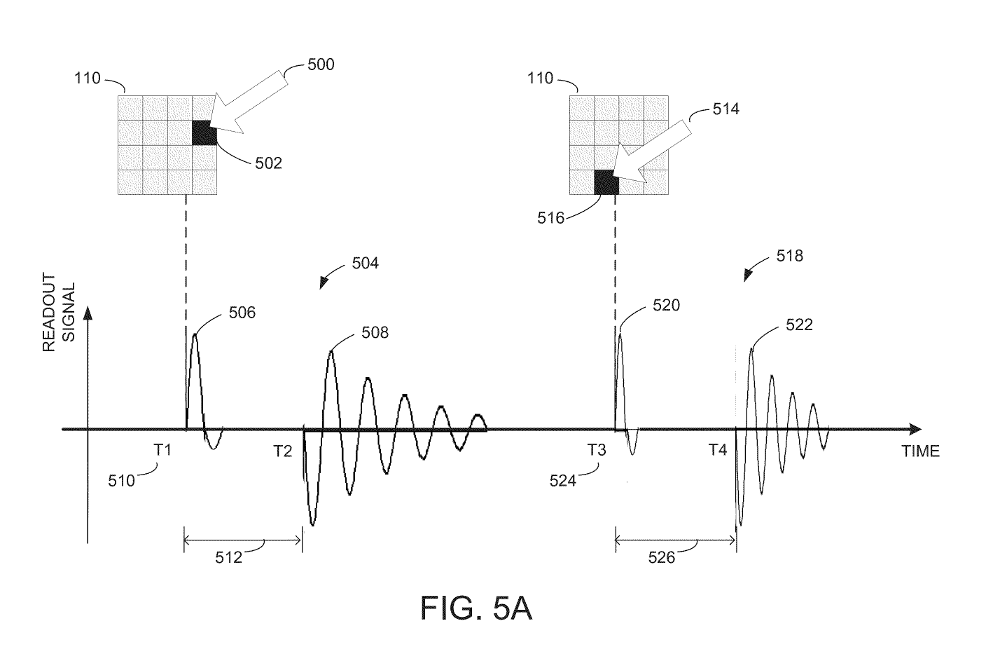

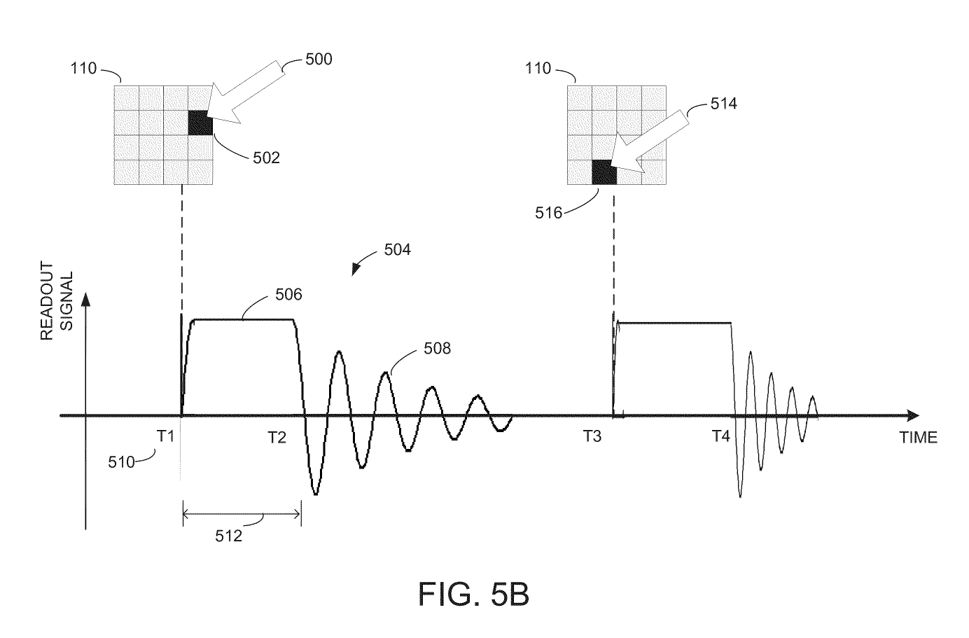

FIGS. 5A and 5B illustrate examples of a transient response that may be generated by a photon detection system 110, such as the photon detection system 110 shown in FIGS. 2A and 2B, respectively. In both examples of FIGS. 5A and 5B, the transient responses of two resonant cells are illustrated. The first excited resonant cell has a lower resonant frequency than the second excited resonant cell.

In the example of FIG. 5A, each resonator has an internal series configuration (as in FIG. 3A) and the resonant cells are coupled to each other in parallel (as in FIG. 2A). The nanowires in each resonant cell are superconducting initially, and a photon 500 is absorbed in the first and second resonant cells at T1 and T3, respectively.

When the first resonant cell 502 absorbs a photon 500 at time T1, it emits a transient response 504. The transient response 504 comprises two pulses, a first pulse 506 and a second pulse 508. When a photon strikes at time T1 (labeled 510, the nanowire becomes highly resistive, forming a large voltage pulse and immediately becoming an extremely poor resonator. This causes the first pulse 506 at T1 with a small amount of oscillation that is highly damped by the resistive nanowire.

After the photon is absorbed at time T1, the nanowire in the resonant cell 502 remains resistive for a duration labeled by 512. This duration 512 corresponds to the reset time of the resonant cell, and may be of approximately one nanosecond. After the duration 512, the nanowire becomes superconducting again at time T2.

After the approximately 1 ns of being resistive, the nanowire switches back to superconducting state (small resistance), causing current to flow in the reverse direction and causing the second pulse 508 at time T2. At this point though, the nanowire is superconducting and is no longer heavily damped by the nanowire, such that the damping is largely influenced by a damping resistance (such as resistor 308). Thus, the resonant cell 502 is able to ring for a much longer time. In some embodiments, this ringing may be long enough to detect a frequency component within the second pulse 508.

As such, in some embodiments, the time-detection may take place at either the T1 ringing or the T2 ringing. In some embodiments the frequency identification (which identifies which resonant cell was triggered) may only take place at T2.

At time T3, a second photon 514 may arrive at the second resonant cell 516. Similar to the case for the first resonant cell 502, a transient response 518 may be generated, comprising a first pule 520 that is highly dampened, and a second pulse 522 that rings for a longer time. Though, in this example, the ringing has a different frequency, reflecting a different resonant frequency for cell 516 than 502. The time component of the photon arrival may be determined from the start of the first pulse at T3 (labeled 524) or from the start of the second pulse at time T4. The frequency component of the transient response may be determined from the second pulse 522, after a delay indicated by time interval 526, during which the nanowire in resonant cell 516 is highly resistive.

In some embodiments, by separating the detection of the triggering of a transient response from the identification of the resonant cell that caused it, information may be received before a frequency component is resolved from the transient response.

Accurately determining a frequency component within a transient response may be delayed in waiting for multiple oscillations of the transient response. Such limitations may be circumvented by first detecting a time of arrival of a photon, without knowing which resonant cell was struck, and then “listening for note” to retroactively determine the frequency component that identifies which photon detector was struck.

FIG. 5B is a sketch of a readout signal from another example of a photon detection system 110 as a function of time, in accordance with some embodiments. In the example of FIG. 5B, each resonant cell in the photon detection system 110 has an internal parallel configuration (as in FIG. 3B) and the resonant cells are coupled to each other in series (as in FIG. 2B). As in FIG. 5A, there are two resonant cells, each of different resonant frequencies.

When a photon 500 is absorbed by the first resonant cell 502, a transient response 504 is created. The transient response may once again comprise two pulses, a first pulse 506 and a second pulse 508. The first pulse 506 may comprise a brief spike at the photon absorption time T1 (labeled 510) before settling on a DC voltage level. The DC voltage level is a result of increased voltage across the parallel-resonator in resonant cell 502 while its nanowire is resistive.

Initially, the current from a DC bias current goes through superconducting nanowire (capacitors are open at DC). When the photon 500 arrives, it creates a large resistance in the nanowire and a large voltage spike, charging the capacitor parallel. After a delay 512, nanowire becomes superconductive again, which removes the voltage across the parallel capacitor. The parallel capacitor then discharges and creates a current, creates oscillations beginning at time T2. Due to small resistance of the now-superconducting nanowire, the oscillations 508 ring for a certain duration of time, during which the resonant frequency may be detected.

A second photon 514 arriving at the second resonant cell 516 will induce a similar effect, but with a different resonant frequency.

FIGS. 5A and 5B illustrate different transient responses of different frequencies on a common output. In some embodiments, resolving the timing of the transient responses may entail that the transient responses each dissipate quickly enough before another photon arrives at the same cell. Meanwhile, in the frequency domain, accurately resolving between different frequencies may entail separating the resonant frequencies by sufficiently large gaps.

One possible parameter that can be used to control both the time spread and frequency spread of each transient response is known in the art as the quality factor, or “Q” factor, of a resonator. The Q factor is determined by the electrical properties of each resonant cell, namely the resistance, capacitance, and inductance. A large value of Q leads to narrow footprint in frequency, but a longer-lasting signal (long ringing). Thus, designing a photon detection system to accurately detect both a time and frequency component of a transient may involve tuning the Q parameter to achieve a desired balance between time and frequency spread of the transient responses. Such tuning may be achieved by selection of damping components, such as inductor 306 and resistor 308.

FIGS. 5A-5B depict two different types of transient responses that result from resonant cells being excited by a photon absorption. In both FIGS. 5A and 5B, the transient responses included pulses that result from a sudden increase and decrease in voltage across a temporarily non-superconducting (highly resistive) nanowire. As described previously, the exact nature of the transient response depends on how the resonant cells are coupled with each other, and the internal structure of each resonant cell. FIG. 5A corresponds to resonant cells coupled in parallel (as in FIG. 2A) and having internal series resonance (as in FIG. 3A). FIG. 5B corresponds to resonant cells coupled in series (as in FIG. 2B) and having internal parallel resonance (as in FIG. 3B).

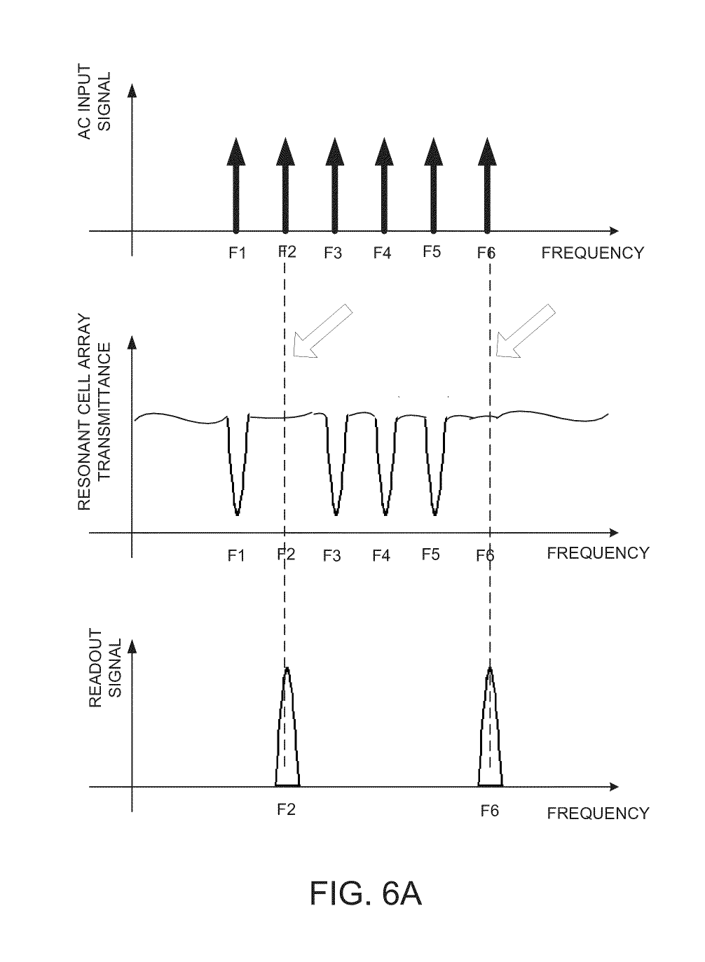

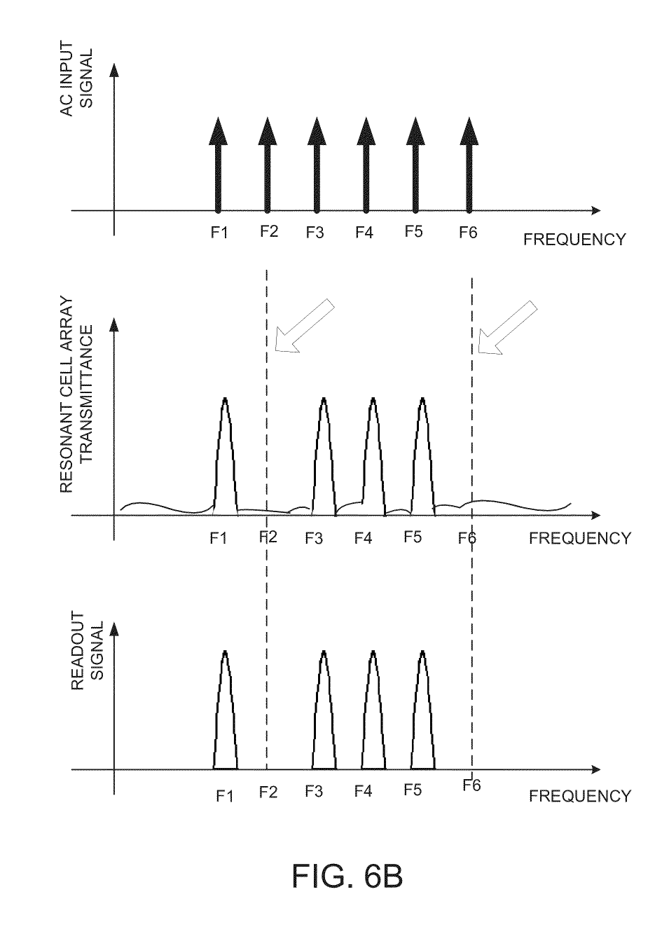

Other resonant cell configurations are possible, leading to yet other types of transient responses at the readout line. For example, an AC source may be used to “probe” each resonant cell at its resonant frequency. Examples of such configurations were shown in FIGS. 2C to 2E. The particular resonant characteristics of each resonant cell will filter the AC source in different ways, leading to changes in the output at the readout line. For example, when a photon is absorbed, a resonant cell may either pass or reflect its corresponding AC source. This may be detected on the readout line by detecting a decrease or increase in the amplitude of the frequency component corresponding to that AC source. Examples of such filtering are shown in FIGS. 6A and 6B.

FIG. 6A is a sketch conceptually illustrating frequency filtering of an AC input source with multiple frequency components by an array of resonant cells, in accordance with some embodiments. For example, this filtering may correspond to resonant cells coupled in parallel (e.g., FIG. 2C) with each resonant cell having a series resonance structure (e.g., FIG. 3A).

The top sketch of FIG. 6A illustrates a frequency plot of a an AC source that sends a probe signal containing multiple frequency components, or tones. Each tone may correspond to a frequency of a resonant cell. Although six tones are depicted, it should be appreciated that any number of tones may be used, corresponding to the number of resonant cells. Depending on the structure of the resonant cells, the AC probe signals may be filtered in various ways to indicate an arrival of a photon. The resulting filtered AC probe signals may be read on a common readout line (e.g., readout line 206 of FIG. 2C).

The middle sketch of FIG. 6A illustrates one possible filtering characteristic of an array of resonant cells, such as the resonant cell configuration shown in FIG. 2C. In the configuration of FIG. 2C, each resonant cell may be a series resonator (e.g., FIG. 3A). Resonant cells that do not detect any photons may have low impedance at its resonance frequency. This may create a short circuit through which the corresponding AC source may be shunted to ground, away from the readout line 206. Thus, the corresponding AC sources are blocked from reaching the readout line 206, and the tones for those resonant cells would not be detectable at the output (e.g., at frequencies F1, F3, F4, and F5 in FIG. 6A). In terms of a filtering perspective, the input-output filter characteristic of the resonant cell may be described as a “notch” filter that blocks output transmittance of input signals at its resonant frequency.

For those resonant cells that absorb a photon, the resonant cell has a high Q factor and is no longer a short circuit at its resonant frequency. Thus, signals at those frequencies do not fully pass to ground and are able to reach the readout line. From a filtering perspective, the resonant cell may be viewed as momentarily dropping the notch in the filter at its resonant frequency (e.g., frequencies F2 and F6 in FIG. 6A). Thus, a photon absorption may be detected by determining which AC sources are transmitted to the output in the readout line.

In the middle sketch of FIG. 6A, resonant cells corresponding to resonant frequencies F2 and F6 have absorbed photons. This causes signals at those frequencies to temporarily reach the output, and thus an increase in amplitude at the output readout line for those frequency components, as shown in the bottom sketch of FIG. 6A.

FIG. 6B is a sketch conceptually illustrating frequency filtering of AC input source with multiple frequency components by an array of resonant cells, in accordance with some alternative embodiments. For example, FIG. 6B may describe a filtering characteristic of resonant cells coupled in series (e.g., as shown in FIGS. 2D and 2E).

In the examples of FIGS. 2D and 2E, each resonant cell may be a parallel resonator (e.g., FIG. 3B). In steady state, those resonant cells that have not absorbed any photons may have high impedance at resonance frequency. This may create an open circuit which allows the corresponding tone to reach the readout line 206. Thus, the readout line 206 may show output spikes at the resonant frequencies corresponding to those resonant cells (e.g., frequencies F1, F3, F4, and F5 in FIG. 6B). In terms of a filtering perspective, the input-output filter characteristic of the resonant cell may be described as a pass-through band-pass filter that transmits input signals at each resonant frequency.

For those resonant cells that have absorbed photons, the Q factor changes and the resonant cells are no longer an open circuit at resonance frequency. Thus, signals at those frequencies are shunted to ground through the resonant cells, away from the readout line. From a filtering perspective, the resonant cells may be viewed as being a notch filter at its resonant frequency. Thus, a photon absorption may be detected by determining which tones are blocked from reaching the readout line (e.g., at frequencies F2 and F6 in FIG. 6B).

For example, in the middle sketch of FIG. 6B, resonant cells corresponding to resonant frequencies F2 and F6 have absorbed photons. This causes a temporary condition during which signals at those frequencies do not reach the output line, and thus a decrease in amplitude at the output readout line for those frequency components, as shown in the bottom sketch of FIG. 6B.

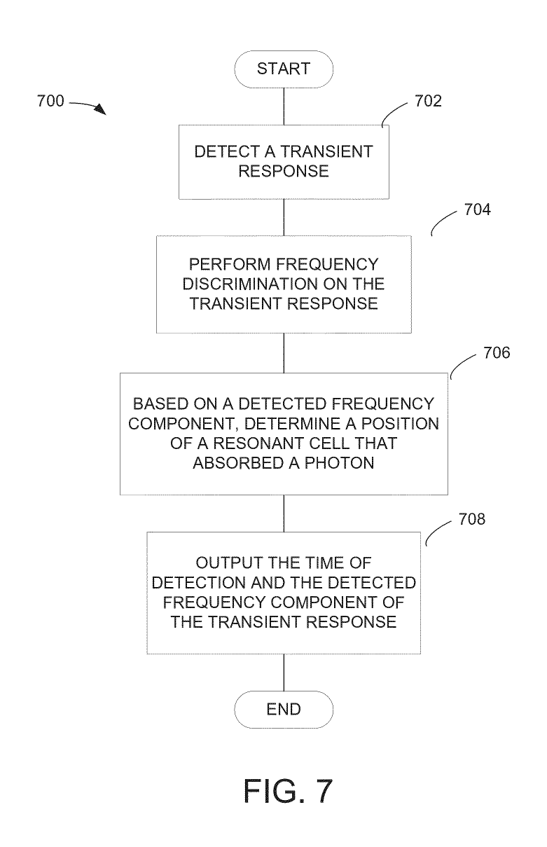

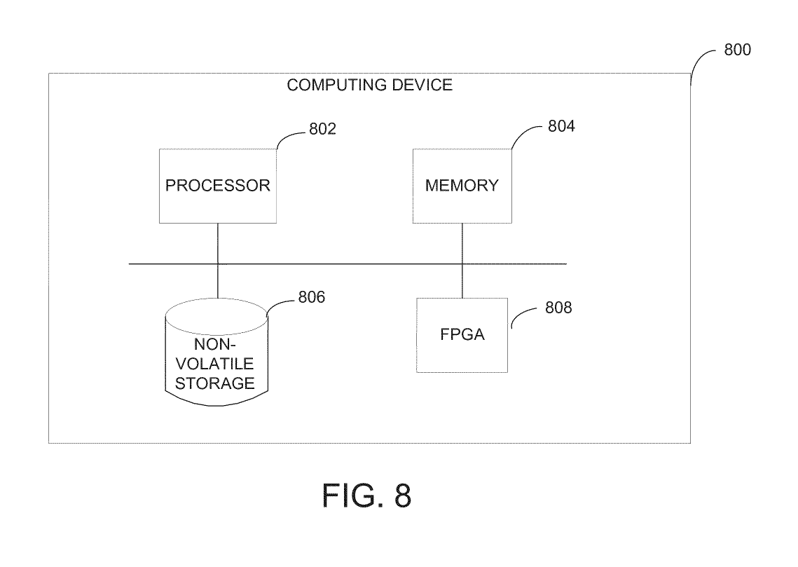

FIG. 7 is a flow chart of an exemplary method 700 of receiving information with a photon detection system, in accordance with some embodiments. Such a method may be implemented, for example, by readout circuitry coupled to a plurality of resonant cells. In step 702, a transient response is detected on a readout line. The transient response may include one or more pulses, each indicating a time and/or a frequency component of an excitation of a resonant cell. In step 702, a timing of the transient response may be determined, and the timing may be used to decode some information.

In step 704, a frequency component of the transient response may be determined by performing frequency discrimination on the transient response. The frequency discrimination may be performed, for example, using a frequency discriminator, such as a DFD. Any suitable implementation may be used for such a DFD, such as, for example, programming in programmable gate array (PGA or FPGA), as is known in the art. Regardless of the exact nature of the frequency discrimination, a frequency component may be detected from the transient response.

In step 706, the detected frequency component may be used to determine a position of a resonant cell that absorbed a photon. In some embodiments, the frequency component may correspond to a resonant frequency of a resonant cell, which may be emitted when the resonant cell is struck by a photon. Though, as described above, other configurations of resonant cells may produce a measurable response in any other ways, and these techniques alternatively or additionally may be used. The location of the resonant cell may be correlated with the detected frequency component by accessing a database of locations, for example, or by any suitable method of mapping frequency to position.

In step 708, both the detected time and position of the photon arrival may be output. The output of the time and position may happen simultaneously or may happen at different times. For example, if the time of photon arrival is detected first, then the time may be output before the position.

FIG. 8 illustrates an illustrative implementation of a computer system 800 that may be used to implement one or more of the transformation techniques described herein, either to detect a frequency component (e.g., in frequency detector 112 of FIG. 1 may be implemented by performing a frequency transform on sampled signals on the output line) or to generate a digital code (e.g., in digital code generation circuit 116 of FIG. 1). Computer system 800 may include one or more processors 802 and one or more non-transitory computer-readable storage media (e.g., memory 804 and one or more non-volatile storage media 806). The processor 802 may control writing data to and reading data from the memory 804 and the non-volatile storage device 806 in any suitable manner, as the aspects of the invention described herein are not limited in this respect. To perform functionality and/or techniques described herein, the processor 802 may execute one or more instructions stored in one or more computer-readable storage media (e.g., the memory 804, storage media, etc.), which may serve as non-transitory computer-readable storage media storing instructions for execution by the processor 802. Computer system 800 may also include any other processor, controller or control unit needed to route data, perform computations, perform I/O functionality, etc.

In connection with the transformation techniques described herein, one or more programs that evaluate data, determine frequency components, and generate digital codes, may be stored on one or more computer-readable storage media of computer system 800. Processor 802 may execute any one or combination of such programs that are available to the processor by being stored locally on computer system 800 or accessible over a network. Any other software, programs or instructions described herein may also be stored and executed by computer system 800. Computer 800 may be a standalone computer, mobile device, etc., and may be connected to a network and capable of accessing resources over the network and/or communicate with one or more other computers connected to the network.

In some embodiments, additional hardware components, such as a field programmable gate array (FPGA) 808, may be used to execute computer-readable instructions that may implement one or more functions described herein. For example, an FPGA may be programmed to perform frequency detection by correlating a readout signal with each of the known resonant tones for the resonant cells. It should be appreciated, however, that any suitable hardware component may be used to implement computer-readable instructions, as the invention is not limited in this regard.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A photon detection system, comprising:
an output line;
a plurality of resonant cells coupled to the output line, each resonant cell comprising a nanowire, wherein each of the plurality of resonant cells is configured to provide a different resonant frequency; and
a frequency detector coupled to the output line, the frequency detector configured to detect on the output line transient responses of the plurality of resonant cells.

2. The photon detection system of claim 1, wherein:
the frequency detector is further configured to indicate a frequency component and a time of initiation of a transient response of any of the plurality of resonant cells.

3. The photon detection system of claim 2, further comprising:
a digital code generation circuit coupled to the frequency detector, the digital code generator configured to generate a digital code representing a combination of a value selected based on a detected frequency component and a value indicative of a time of initiation of the transient response.

4. The photon detection system of claim 3, wherein an amount of information represented by the combination of the value selected based on the detected frequency component and the time of initiation of the transient response is proportional to an amount of information represented by the product of the value selected based on the detected frequency component and the value indicative of the time of initiation of the transient response.

5. The photon detection system of claim 4 in combination with components comprising a communication system, the components comprising the communication system comprising an interface to an optical communication medium, the interface configured to couple photons from a communications medium to the photon detection system.

6. The photon detection system of claim 1, wherein:
each of the plurality of resonant cells comprises a capacitor coupled to a respective nanowire of the resonant cell.

7. The photon detection system of claim 6, wherein each of the plurality of resonant cells has a capacitor of a different size and/or a nanowire of a different length.

8. The photon detection system of claim 6, wherein:
the plurality of resonant cells are coupled in parallel; and
in each of the plurality of resonant cells, the capacitor is coupled in series with the nanowire.

9. The photon detection system of claim 6, wherein:
the plurality of resonant cells are coupled in series; and
in each of the plurality of resonant cells, the capacitor is coupled in parallel with the nanowire.

10. The photon detection system of claim 1, further comprising:
at least one AC coupling component coupling the plurality of resonant cells to the output line.

11. The photon detection system of claim 10, further comprising:
at least one DC bias source coupled to each of the plurality of nanowires.

12. The photon detection system of claim 11, further comprising:
at least one AC source coupled to the output line, the at least one AC source oscillating with a frequency substantially matched to a resonant frequency of at least one resonant cell of the plurality of resonant cells.

13. The photon detection system of claim 12, wherein:
the plurality of resonant cells are coupled in parallel; and
each of the plurality of resonant cells comprises a capacitor coupled in series to a respective nanowire of the resonant cell.

14. The photon detection system of claim 12, wherein:
the plurality of resonant cells are coupled in series; and
each of the plurality of resonant cells comprises a capacitor coupled in parallel to a respective nanowire of the resonant cell.

15. The photon detection system of claim 1, wherein:
each of the plurality of resonant cells comprises a superconducting nanowire single-photon detector (SNSPD).

16. The photon detection system of claim 1, wherein:
the photon detection system is constructed and arranged to detect a photon of at least one frequency greater than a frequency of infrared electromagnetic radiation.

17. The photon detection system of claim 1, wherein:
the photon detection system is constructed and arranged to detect a photon of at least one frequency of microwave electromagnetic radiation.

18. The photon detection system of claim 3, wherein:
at least one of the frequency detector and the digital code generation circuit are configured to operate at room temperature.

19. The photon detection system of claim 2, wherein:
the transient response comprises at least a first pulse and a second pulse; and
the frequency detector is further configured to indicate the time of initiation of the transient response based on the first pulse, and to indicate the frequency component of the transient response based on the second pulse.

20. The photon detection system of claim 1, wherein:
the frequency detector comprises at least one of a frequency discriminator and a field-programmable gate array (FPGA).

21. The photon detection system of claim 1, wherein:
the nanowire is configured in a serpentine pattern.

22. The photon detection system of claim 1, wherein:
the nanowire is superconducting and comprises at least one of niobium and tungsten.

23. The photon detection system of claim 1, wherein:
the nanowire has a substantially uniform width between 20 nm and 100 nm.

24. The photon detection system of claim 1, wherein:
the nanowire is positioned on a substrate comprising at least one of sapphire, magnesium, and silicon.

25. The photon detection system of claim 15, wherein:
the SNSPD comprises an active area of size between 9 μm² and 100 μm².

26. A method of receiving information with a photon detection system, the photon detection system comprising a plurality of resonant cells, each of the plurality of resonant cells having a different resonant frequency, the method comprising:
exposing the photon detection system to a source of photons, whereby resonant signals within resonant cells are excited in resonant cells of the plurality of resonant cells by the photons; and
providing an output based on at least one transient response detected at an output of a resonant cell of the plurality of resonant cells, wherein each of the at least one detected transient response corresponds to a resonant frequency of a resonant cell.

27. The method of claim 26, wherein:
detecting at least one transient response comprises detecting a single frequency component; and
the method further comprises providing an indication of a position at which a single photon struck the photon detection system based on the detected single frequency component.

28. The method of claim 27, wherein:
the plurality of resonant cells are coupled to a common output line; and
detecting the single frequency component comprises performing a frequency analysis on a signal on the output line.

29. The method of claim 26, wherein:
providing the output comprises providing the output based on at least one frequency component of the at least one transient response detected at an output of a resonant cell of the plurality of resonant cells and a time of detection of each of the at least one transient response.

30. The method of claim 27, wherein detecting the single frequency component comprises detecting an increase in amplitude of the single frequency component.

31. The method of claim 27, further comprising:
exciting at least one resonant cell of the plurality of resonant cells with an AC input oscillating with a frequency substantially matched to a resonant frequency of the at least one resonant cell of the plurality of resonant cells.

32. The method of claim 31, wherein detecting the single frequency component comprises detecting a decrease in amplitude of the single frequency component.

33. The method of claim 31, wherein detecting the single frequency component comprises detecting an increase in amplitude of the single frequency component.

34. The method of claim 27, wherein:
each of the plurality of resonant cells comprises a superconducting nanowire single-photon detector (SNSPD).

35. The method of claim 26, wherein:
the photon detection system is constructed and arranged to detect at least one frequency greater than a frequency of infrared electromagnetic radiation.

36. The method of claim 26, wherein:
the photon detection system is constructed and arranged to detect at least one frequency of microwave electromagnetic radiation.

37. The method of claim 29, wherein:
the at least one transient response comprises at least a first pulse and a second pulse; and
providing the output comprises providing the output based on at least one frequency component of the at least one transient response detected at an output of a resonant cell of the plurality of resonant cells and a time of detection of each of the at least one transient response further comprises:
providing the output based on at least one frequency component of the second pulse and a time of detection of the first pulse.

38. At least one computer-readable storage medium comprising computer executable instructions that, when executed by a computing device, perform a method, the method comprising:
receiving a signal from a photon detection system;
computing a position based on a change in amplitude of at least one frequency component of the signal; and
computing a time of initiation of the change in amplitude of the at least one frequency component of the signal.

39. The at least one computer-readable storage medium of claim 38, wherein computing the position based on the change in amplitude of the at least one frequency component comprises:
computing the position at which a single photon struck the photon detection system, based on a change in amplitude of a single frequency component of the signal.

40. The at least one computer-readable storage medium of claim 39, wherein:
the photon detection system comprises a plurality of resonant cells coupled to a common output line; and
the single frequency component of the signal corresponds to a resonant cell located at the position at which the single photon struck the photon detection system.

41. The at least one computer-readable storage medium of claim 39, wherein computing the position based on the change in amplitude of the single frequency component comprises:
computing an amount of increase in amplitude of the single frequency component.

42. The at least one computer-readable storage medium of claim 40, further comprising:
exciting at least one resonant cell of the plurality of resonant cells with an AC input coupled to the common output line, the AC input oscillating with a frequency substantially matched to a resonant frequency of the at least one resonant cell.

43. The at least one computer-readable storage medium of claim 42, wherein detecting the single frequency component comprises detecting a decrease in amplitude of the single frequency component.

44. The at least one computer-readable storage medium of claim 42, wherein detecting the single frequency component comprises detecting an increase in amplitude of the single frequency component.

45. The at least one computer-readable storage medium of claim 39, wherein:
computing the position based on the change in amplitude of the at least one frequency component comprises performing a frequency analysis on the signal on the output line.

46. The at least one computer-readable storage medium of claim 45, wherein:
the computer executable instructions, when executed by the computing device, further implement a digital frequency discriminator (DFD); and
performing a frequency analysis comprises using the DFD.

47. The at least one computer-readable storage medium of claim 38, further comprising:
providing an output based on the computed position and the computed time.

48. The at least one computer-readable storage medium of claim 47, wherein providing an output comprises:
decoding information from the received signal, based at least in part on the computed position and the computed time.

49. The at least one computer-readable storage medium of claim 40, wherein:
each of the plurality of resonant cells comprises a superconducting nanowire single-photon detector (SNSPD).

50. The at least one computer-readable storage medium of claim 38, wherein:
the photon detection system is constructed and arranged to detect at least one frequency of infrared electromagnetic radiation.

51. The at least one computer-readable storage medium of claim 38, wherein:
the photon detection system is constructed and arranged to detect at least one frequency of microwave electromagnetic radiation.
